(19) United States
(12) Patent Application Publication
(10) Pub. No.: US 2025/0241209 A1
(43) Pub. Date: Jul. 24, 2025

(54) MAGNETORESISTIVE RANDOM ACCESS MEMORY DEVICE

(71) Applicant: SAMSUNG ELECTRONICS CO., LTD., SUWON-SI (KR)

(72) Inventor: Jonghyuk Lee, Suwon-si (KR)

(21) Appl. No.: 18/774,426

(22) Filed: Jul. 16, 2024

(30) Foreign Application Priority Data
Jan. 23, 2024 (KR) 10-2024-0010404

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A magnetoresistive random access memory device includes a cell region and a core peri region on a substrate; a first interlayer insulation layer disposed on the substrate; a second interlayer insulation layer disposed on the first interlayer insulation layer; a first wiring line disposed in the first interlayer insulation layer; a lower electrode contact disposed on the first wiring line in the cell region; and first and second information storage structures disposed on the lower electrode contact in the cell region, wherein each of the first and second information storage structures includes a lower electrode and a magnetic tunnel junction (MTJ) structure disposed on the lower electrode. The first information storage structure includes an upper electrode disposed on the MTJ structure and a first barrier layer on each sidewall of the upper electrode, and the second information storage structure includes a second barrier layer disposed on the MTJ structure.

### CROSS-REFERENCE TO RELATED APPLICATION

This application claims priority under 35 U.S.C. § 119 from Korean Patent Application No. 10-2024-0010404, filed on Jan. 23, 2024 in the Korean Intellectual Property Office, the contents of which are herein incorporated by reference in their entirety.

### TECHNICAL FIELD

Embodiments of the inventive concept are directed to a semiconductor device, and more particularly, to a magnetoresistive random access memory (MRAM) device.

### DISCUSSION OF THE RELATED ART

As electronic devices increase in speed and decrease in power, the demand for a high processing speed and/or a low operating voltage of a semiconductor device IS increasing. To meet such demand, MRAM devices have been proposed as semiconductor devices. MRAM devices have characteristics such as a high-speed operation and/or non-volatility and are thus attracting much attention as next-generation semiconductor devices.

In general, MRAM devices include a magnetic tunnel junction (MTJ). An MTJ includes two magnetic materials and an insulation layer disposed therebetween. A resistance value of an MTJ varies depending on the magnetization directions of the two magnetic materials. For example, when the magnetization directions of the two magnetic materials are anti-parallel to each other, MTJs have a large resistance value, and when the magnetization directions of the two magnetic materials are parallel to each other, MTJs have a small resistance value. Data can be written/read by using the resistance value difference.

### SUMMARY

Embodiments of the inventive concept provide a magnetoresistive random access memory (MRAM) device with increased performance and reliability.

Embodiments of the inventive concept provide a magnetoresistive random access memory (MRAM) device.

A magnetoresistive random access memory device according to an embodiment includes a cell region and a core peri region arranged in a first horizontal direction on a substrate, a first interlayer insulation layer disposed on the substrate in the cell region and the core peri region, a second interlayer insulation layer disposed on the first interlayer insulation layer, a first wiring line disposed in the first interlayer insulation layer in the cell region and the core peri region, a lower electrode contact disposed on the first wiring line in the cell region, and first and second information storage structures disposed on the lower electrode contact in the cell region. Each of the first and second information storage structures include a lower electrode and a magnetic tunnel junction (MTJ) structure disposed on the lower electrode. The first information storage structure further includes an upper electrode disposed on the MTJ structure and a first barrier layer disposed on each sidewall of the upper electrode, and the second information storage structure further includes a second barrier layer disposed on the MTJ structure.

A magnetoresistive random access memory device according to an embodiment includes a cell region and a core peri region arranged in a first horizontal direction on a substrate, a lower conductive region disposed in the cell region and the core peri region, a first wiring structure that is connected to the lower conductive region in the cell region and the core peri region, a lower electrode contact connected to the first wiring structure in the cell region, and a first information storage structure disposed on the lower electrode contact. The first information storage structure includes a lower electrode disposed on the lower electrode contact, a magnetic tunnel junction (MTJ) structure disposed on the lower electrode, and an upper electrode spaced apart from the lower electrode with the MTJ structure interposed therebetween. The first information storage structure further includes a first barrier layer conformally disposed on both sidewalls of the upper electrode.

A magnetoresistive random access memory device according to an embodiment includes a cell region and a core peri region arranged in a first horizontal direction on a substrate, lower conductive region disposed in the cell region and the core peri region, first wiring structure that is connected to the lower conductive region in the cell region and the core peri region, an interlayer insulation layer disposed on the substrate in the cell region and the core peri region, wiring lines that pass through the interlayer insulation layer and are connected to the lower conductive region in the cell region and the core peri region, a lower electrode contact disposed on the wiring lines, a first information storage structure disposed on a first portion of the lower electrode contact, where the first information storage structure includes a lower electrode, a magnetic tunnel junction (MTJ) structure, and an upper electrode that are sequentially stacked, a second information storage structure disposed on a second portion of the lower electrode contact, where the second information storage structure includes a lower electrode, the MTJ structure, and an upper barrier layer that are sequentially stacked, and a barrier layer that includes titanium oxide and is conformally formed along each sidewall of the upper electrode of the first information storage structure. A vertical level of the wiring lines in the cell region and the core peri region is lower than or coplanar with a vertical level of a lower surface of the MTJ structure.

### BRIEF DESCRIPTION OF THE DRAWINGS

FIG. 1 is a circuit diagram of a unit memory cell of a magnetoresistive random access memory (MRAM) device according to embodiments.

FIG. 2 is a cross-sectional view of an MRAM device according to embodiments.

FIG. 3 is a cross-sectional view of an information storage structure of an MRAM device according to embodiments.

FIGS. 4A and 4B are cross-sectional views of examples of an information storage structure of an MRAM device according to embodiments.

FIG. 5 is an enlarged cross-sectional view of a region EX of FIG. 2.

FIGS. 6 to 18 are cross-sectional views that illustrate a method of manufacturing an MRAM device, according to embodiments.

### DETAILED DESCRIPTION

Hereinafter, embodiments will be described in detail with reference to the accompanying drawings. Like reference numerals may refer to like elements in the drawings, and their repeated descriptions may be omitted.

Embodiments are provided so that this disclosure will be thorough and complete, and will fully convey the concept of the inventive concept to one of ordinary skill in the art. However, this does not limit the inventive concept within specific embodiments and it should be understood that the inventive concept covers all the modifications, equivalents, and replacements within the idea and technical scope of the inventive concept.

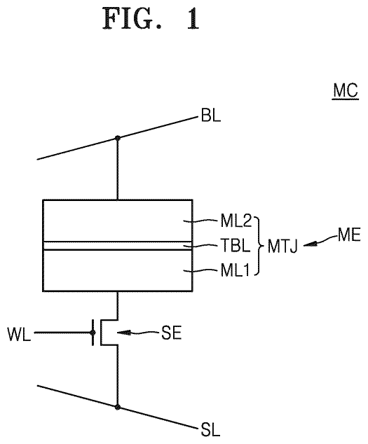

FIG. 1 is a circuit diagram of a unit memory cell MC of a magnetoresistive random access memory (MRAM) device according to embodiments.

Referring to FIG. 1, in an embodiment, the unit memory cell MC includes a memory device ME and a selection element SE. The memory device ME and the selection element SE are electrically and serially connected to each other. The memory device ME is connected between a bit line BL and the selection element SE. The selection element SE is connected between the memory device ME and a source line SL and is controlled by a word line WL. The selection element SE includes, for example, one of a bipolar transistor or a metal oxide silicon field effect transistor (MOSFET).

The memory device ME includes a magnetic tunnel junction MTJ that includes magnetic layers ML1 and ML2 that are spaced apart from each other and a tunnel barrier TBL between the magnetic layers ML1 and ML2. One of the magnetic layers ML1 or ML2 is a reference layer that has a magnetization direction fixed to one direction regardless of an external magnetic field in a common use environment. The other of the magnetic layers ML1 or ML2 is a free layer whose magnetization direction changes between two stable magnetization directions by an external magnetic field or a current. An electrical resistance of the magnetic tunnel junction MTJ is higher when the magnetization directions of the reference layer and the free layer are parallel to each other than when the magnetization directions of the reference layer and the free layer are antiparallel to each other. For example, the electrical resistance of the magnetic tunnel junction MTJ can be adjusted by changing the magnetization direction of the free layer. Accordingly, the memory device ME can store data in the unit memory cell MC by using the electrical resistance difference caused by the magnetization directions of the reference layer and the free layer.

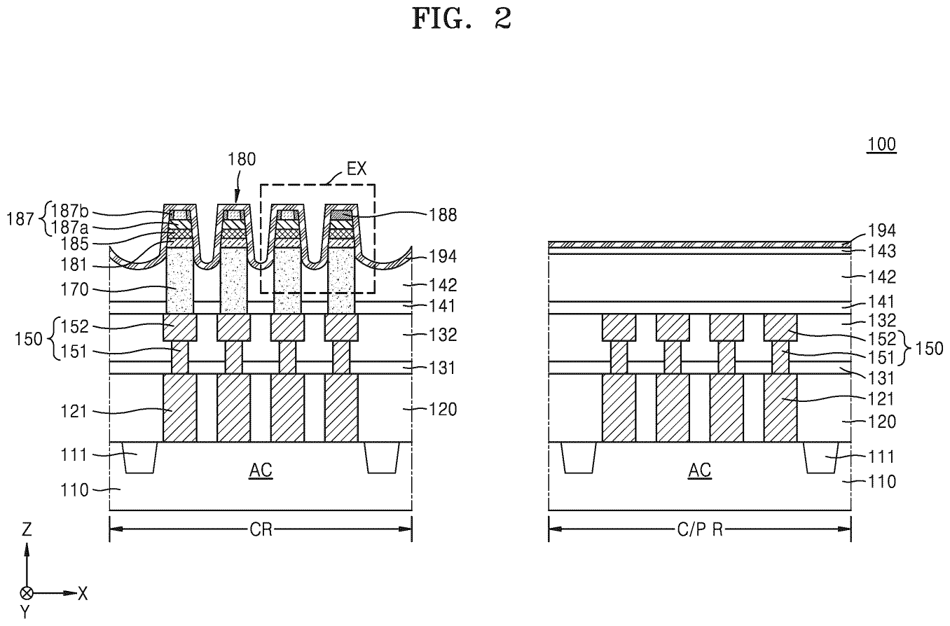

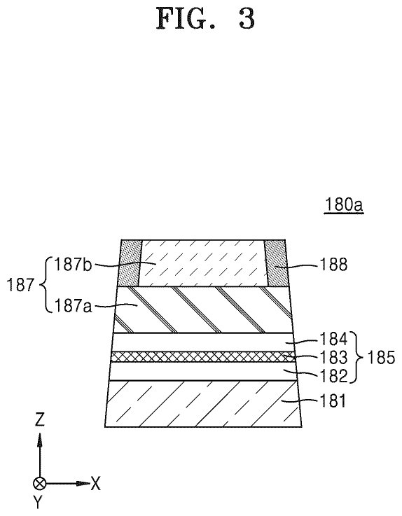

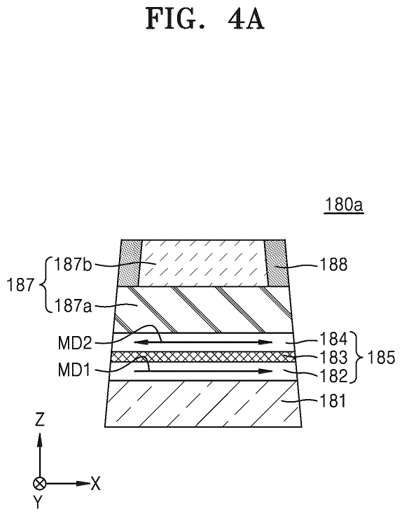

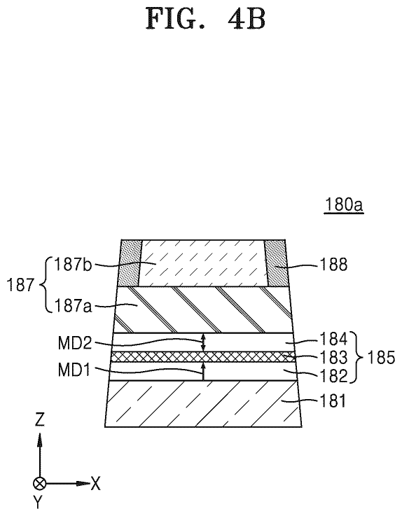

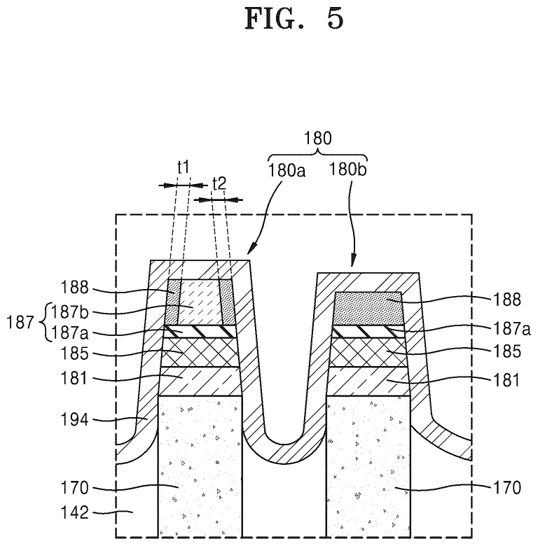

FIG. 2 is a cross-sectional view of an MRAM device 100 according to embodiments. FIG. 3 is a cross-sectional view of an information storage structure 180 of the MRAM device 100 according to embodiments. FIGS. 4A and 4B are cross-sectional views of examples of the information storage structure 180 of the MRAM device 100 according to embodiments. FIG. 5 is an enlarged cross-sectional view of a region EX of FIG. 2.

Referring to FIG. 2, in an embodiment, the MRAM device 100 include a substrate 110 that includes a cell region CR and a core/peri region C/P R. In the substrate 110, the cell region CR and the core/peri region C/P R are arranged in a first horizontal direction (an X direction).

The substrate 110 may include a semiconductor element, such as silicon (Si) or germanium (Ge), or a compound semiconductor, such as at least one of silicon carbide (SiC), gallium arsenide (GaAs), indium arsenide (InAs), or indium phosphide (InP). The substrate 110 includes structures that include a semiconductor substrate, at least one insulation layer formed on the semiconductor substrate, and at least one conductive region. The conductive region includes, for example, an impurity-doped well or an impurity-doped structure. A device isolation layer 111 that defines a plurality of active regions AC is formed in the substrate 110. The device isolation layer 111 includes one of oxide, nitride, or a combination thereof. In embodiments, the device isolation layer 111 has various structures, such as a shallow trench isolation (STI) structure.

A lower interlayer insulation layer 120, a lower conductive region 121, a first etch stop layer 131, a first interlayer insulation layer 132, a second etch stop layer 141, and a second interlayer insulation layer 142 are disposed in the cell region CR and the core/peri region C/P R of the substrate 110.

The lower interlayer insulation layer 120 includes an insulation layer that includes one of oxide, silicon nitride, or a combination thereof. The lower conductive region 121 passes through the lower interlayer insulation layer 120 and is connected to the plurality of active regions AC of the substrate 110. The lower conductive region 121 includes various conductive regions and may, for example, include a wiring layer, a contact plug, and a transistor. The lower conductive region 121 includes one of polysilicon, a metal, a conductive metal nitride, a metal silicide, or a combination thereof.

The first etch stop layer 131 and the first interlayer insulation layer 132 are disposed on the lower interlayer insulation layer 120. The first etch stop layer 131 includes a nitride such as one of silicon nitride (SiN), silicon oxynitride (SiON), silicon carbonitride (SiCN), or silicon oxycarbonitride (SiOCN). The first interlayer insulation layer 132 includes an insulation layer that includes one of an oxide, silicon nitride, or a combination thereof.

A first wiring structure 150 that passes through the first etch stop layer 131 and the first interlayer insulation layer 132 is disposed in the cell region CR and the core/peri region C/P R of the substrate 110. The first wiring structure 150 includes a first wiring via 151 and a second wiring line 152. The first wiring structure 150 includes at least one of a metal or a conductive metal nitride. The first wiring structure 150 includes, for example, copper. The first wiring via 151 of the first wiring structure 150 is connected to the lower conductive region 121. For example, in an embodiment, the first wiring via 151 of the first wiring structure 150 is physically and electrically connected to the lower conductive region 121.

The second etch stop layer 141 and the second interlayer insulation layer 142 each cover the first interlayer insulation layer 132 and are disposed in the cell region CR and the core/peri region C/P R of the substrate 110. The second etch stop layer 141 includes a nitride such as at least one of SiN, SiON, SiCN, or SiOCN. The second interlayer insulation layer 142 includes an insulation layer that includes one of an oxide, silicon nitride, or a combination thereof.

A lower electrode contact 170 is disposed in the cell region CR of the substrate 110. The lower electrode contact 170 passes through the second etch stop layer 141 and the second interlayer insulation layer 142 and is connected to the first wiring structure 150.

An upper etch stop layer 143 is disposed on the second interlayer insulation layer 142 in the core/peri region C/P R of the substrate 110. The upper etch stop layer 143 includes a nitride such as at least one of SiN, SiON, SiCN, or SiOCN.

As illustrated in FIG. 2, in an embodiment, the first wiring structure 150 that passes through the first interlayer insulation layer 132 and the lower electrode contact 170 that passes through the second interlayer insulation layer 142 are disposed in the cell region CR. An information storage structure 180 is disposed on the lower electrode contact 170.

In some embodiments, the first wiring structure 150 passes through the first interlayer insulation layer 132 and is disposed in the first interlayer insulation layer 132 in the cell region CR and the core/peri region C/P R. For example, the first wiring via 151 passes through the first etch stop layer 131 and extends into the first interlayer insulation layer 132, and the first wiring line 152 is disposed in the first interlayer insulation layer 132 on the first wiring via 151.

In some embodiments, a vertical level of an upper surface of the first interlayer insulation layer 132 is coplanar with a vertical level of an upper surface of the first wiring structure 150.

In some embodiments, the lower electrode contact 170 passes through the second interlayer insulation layer 142 and is disposed in the second interlayer insulation layer 142 in the cell region CR. For example, the lower electrode contact 170 passes through the second etch stop layer 141 and extends into the second interlayer insulation layer 142. For example, the lower electrode contact 170 includes a portion surrounded by each of the second etch stop layer 141 and the second interlayer insulation layer 142. The lower electrode contact 170 is connected to the first wiring structure 150.

In some embodiments, the lower electrode contact 170 makes contact with the first wiring structure 150. For example, the lower electrode contact 170 makes contact with the first wiring line 152 of the first wiring structure 150. In some embodiments, the lower electrode contact 170 is disposed only in the cell region CR.

In some embodiments, the upper etch stop layer 143 covers the second interlayer insulation layer 142 and is disposed on the second interlayer insulation layer 142 in the core/peri region C/P R. In some embodiments, an upper surface of the upper etch stop layer 143 in the core/peri region C/P R is disposed at a vertical level that is coplanar with an upper surface of the lower electrode contact 170 in the cell region CR. However, embodiments of the inventive concept are not necessarily limited thereto, and in other embodiments, the upper etch stop layer 143 in the core/peri region C/P R is disposed at a vertical level that is higher than or coplanar with that of the upper surface of the lower electrode contact 170 of the cell region CR.

In some embodiments, the first wiring structure 150 is an uppermost wiring structure in the cell region CR. For example, the first wiring structure 150 is an uppermost wiring structure that is disposed on the substrate 110 and under the lower electrode contact 170 of a plurality of wiring structures in the cell region CR. For example, the first wiring structure 150 is an uppermost wiring structure on which the lower electrode contact 170 makes contact. For example, the first wiring line 152 is an uppermost wiring line in the cell region CR. For example, the first wiring line 151 is an uppermost wiring line on which the lower electrode contact 170 makes contact.

In some embodiments, the first wiring structure 150 is an uppermost wiring structure in the core/peri region C/P R. For example, the first wiring structure 150 is an uppermost wiring structure of a plurality of wiring structures that are disposed on the substrate 110 and are disposed at a vertical level that is lower than or coplanar with a vertical level of the information storage structure 180, in the core/peri region C/P R.

FIG. 2 illustrates that the uppermost wiring structure of the cell region CR and the uppermost wiring structure of the core/peri region C/P R are disposed at the same vertical level, but in other embodiments, the uppermost wiring structure of the cell region CR and the uppermost wiring structure of the core/peri region C/P R are disposed at different vertical levels. For example, the first wiring structure 150 in the cell region CR and the first wiring structure 150 in the core/peri region C/P R are disposed at different vertical levels.

In some embodiments, the lower electrode contact 170 of the cell region CR overlaps the second etch stop layer 141 and the second interlayer insulation layer 142 of the core/peri region C/P R in the first horizontal direction (the X direction).

In some embodiments, a vertical length of the lower electrode contact 170 in the cell region CR is greater than a vertical thickness of the second interlayer insulation layer 142. For example, a vertical height of the lower electrode contact 170 in the cell region CR is greater than the sum of vertical thicknesses of the second interlayer insulation layer 142 and the upper etch stop layer 143.

In some embodiments, a vertical thickness of the second interlayer insulation layer 142 of the cell region CR differs from that of the second interlayer insulation layer 142 of the core/peri region C/P R. For example, vertical levels of lower surfaces of the second interlayer insulation layer 142 of the cell region CR and the second interlayer insulation layer 142 of the core/peri region C/P R may differ, or vertical levels of upper surfaces may differ.

In some embodiments, a vertical level of an upper surface of the lower electrode contact 170 in the cell region CR is lower than that of an upper surface of the upper etch stop layer 143 in the core/peri region C/P R.

Hereinafter, the information storage structure 180 in the cell region CR is described in detail with reference to FIG. 5.

The information storage structure 180 (see FIG. 2) is disposed on the lower electrode contact 170 in the cell region CR of the substrate 110. The information storage structure 180 includes a first information storage structure 180a and a second information storage structure 180b. The first and second information storage structures 180a and 1180b are not provided in the core/peri region C/P R of the substrate 110.

In embodiments, most of the information storage structure 180 disposed in the cell region CR has the shape of the first information storage structure 180a, and at least a portion of the second information storage structure 180b is provided in a dummy cell disposed adjacent to a boundary between the core/peri region C/P R and the cell region CR.

The first information storage structure 180a includes a lower electrode 181, a magnetic tunnel junction (MTJ) structure 185, and an upper electrode 187. The MTJ structure 185 corresponds to the magnetic tunnel junction MTJ described above with reference to FIG. 1. The lower electrode 181 and the upper electrode 187 are spaced apart from each other with the MTJ structure 185 interposed therebetween. The lower electrode 181 is disposed between the MTJ structure 185 and the lower electrode contact 170. The upper electrode 187 includes a first material layer 187a, a second material layer 187b deposited on the first material layer 187a, and a barrier layer 188 that is conformally disposed on both sidewalls of the second material layer 187b. The second material layer 187b of the upper electrode 187 has a trapezoid shape whose width in the first horizontal direction progressively increases toward the substrate. The first barrier layer 188 has a profile inclined along a side surface of the second material layer 187b of the upper electrode 187. The first information storage structure 180a is disposed on the lower electrode contact 170 and is connected to the lower electrode 181.

The second information storage structure 180b includes the lower electrode 181 and the MTJ structure 185 in common with the first information storage structure 180a described above. However, unlike the first information storage structure 180a, the barrier layer 188 instead of the upper electrode is disposed on the MTJ structure 185. The barrier layer 188 in the second information storage structure 180b includes the same material as the barrier layer 188 in the first information storage structure 180a. As described below, the barrier layer 188 in the second information storage structure 180b is formed in the same process as the barrier layer 188 in the first information storage structure 180a.

In embodiments, a first thickness t1 and a second thickness t2 of the barrier layer 188 deposited on each sidewall of the upper electrode 187 of the first information storage structure 180a are equal to each other. In embodiments, the first thickness t1 and the second thickness t2 are each about 2.5 nm, but embodiments of the inventive concept are not necessarily limited thereto. In embodiments, the first thickness t1 and the second thickness t2 do not exceed about 3 nm.

In embodiments, a height of the first information storage structure 180a is greater than that of the second information storage structure 180b. In embodiments, a height of the upper electrode 187 in the first information storage structure 180a is greater than that of the barrier layer 188 in the second information storage structure 180b.

For example, referring to FIG. 3, in an embodiment, the first information storage structure 180a includes a lower electrode 181, an MTJ structure 185, and an upper electrode 187. The MTJ structure 185 includes a first magnetic layer 182 stacked on the lower electrode 181, a tunnel barrier layer 183, and a second magnetic layer 184. The first magnetic layer 182, the tunnel barrier layer 183, and the second magnetic layer 184 correspond to the magnetic layers ML1 and ML2 and the tunnel barrier layer TBL described above with reference to FIG. 1.

The lower electrode 181 includes at least one of a metal such as titanium or tantalum, or a metal nitride such as titanium nitride or tantalum nitride. In embodiments, the lower electrode 181 includes one or more of tungsten, copper, platinum, nickel, silver, or gold. The first material layer 187a in the upper electrode 187 includes titanium nitride. The second material layer 187b in the upper electrode 187 includes at least one of a metal such as titanium or tantalum, or a metal nitride such as titanium nitride or tantalum nitride. For example, the upper electrode 187 includes titanium nitride. The barrier layer 188 includes titanium oxide. In other embodiments, the barrier layer 188 includes another material that has a lower etch rate than silicon oxide.

In some embodiments, the first magnetic layer 182 is a fixed layer whose magnetization direction is fixed. For example, the first magnetic layer 182 includes a fixed pattern, a lower ferromagnetic pattern, an antiferromagnetic coupling spacer pattern, and an upper ferromagnetic pattern. For example, the fixed pattern includes, for example, at least one of iron manganese (FcMn), iridium manganese (IrMn), platinum manganese (PtMn), manganese oxide (MnO), manganese sulfur (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), or chromium (Cr). The upper and lower ferromagnetic patterns include, for example, a ferromagnetic material that includes at least one of iron (Fe), nickel (Ni), or cobalt (Co). The antiferromagnetic coupling spacer pattern includes, for example, at least one of ruthenium (Ru), iridium (Ir), or rhodium (Rh).

In some embodiments, the second magnetic layer 184 is a free layer whose magnetization direction can vary. For example, the second magnetic layer 184 includes a ferromagnetic material such as at least one of Fe, Co, Ni, Cr, or Pt. The second magnetic layer 184 further includes at least one of boron (B) or silicon (Si). The materials can be used individually, or in a combination of two or more materials. For example, the second magnetic layer 184 includes a composite material such as one of CoFe, NiFe, FeCr, CoFeNi, PtCr, CoCrPt, CoFeB, NiFeSiB, or CoFeSiB.

In some embodiments, the tunnel barrier layer 183 is disposed between the first magnetic layer 182 and the second magnetic layer 184. The first magnetic layer 182 and the second magnetic layer 184 are spaced apart from each other with the tunnel barrier layer 183 interposed therebetween. The tunnel barrier layer 183 includes an insulating metal oxide. For example, the tunnel barrier layer 183 includes one of magnesium oxide (MgOₓ) or aluminum oxide (AlOₓ).

Embodiments in which the second magnetic layer 184 is disposed between the tunnel barrier layer 183 and the upper electrode 187 have been described, but embodiments of the inventive concept are not necessarily limited thereto. In some embodiments, the second magnetic layer 184 is disposed between the tunnel barrier layer 183 and the lower electrode 181.

Referring to FIGS. 4A and 4B, in embodiments, the first magnetic layer 182 has a first magnetization direction MD1 fixed to one direction, and the second magnetic layer 184 has a second magnetization direction MD2 that can change to be parallel or antiparallel to the first magnetization direction MD1 of the first magnetic layer 182.

As illustrated in FIG. 4A, in an embodiment, the first and second magnetization directions MD1 and MD2 of the first magnetic layer 182 and the second magnetic layer 184 are parallel to an interface between the tunnel barrier layer 183 and the second magnetic layer 184. For example, each of the first magnetic layer 182 and the second magnetic layer 184 includes a ferromagnetic material. The first magnetic layer 182 further includes an antiferromagnetic material that fixes a magnetization direction of the ferromagnetic material of the first magnetic layer 182.

As illustrated in FIG. 4B, in an embodiment, the first and second magnetization directions MD1 and MD2 of the first magnetic layer 182 and the second magnetic layer 184 are perpendicular to the interface between the tunnel barrier layer 183 and the second magnetic layer 184. For example, each of the first magnetic layer 182 and the second magnetic layer 184 includes at least one of a vertical magnetic material, such as CoFeTb, CoFeGd, or CoFeDy, a vertical magnetic material that has an L10 structure, CoPt, which has a hexagonal close packed lattice structure, or a vertical magnetic structure. The L10 structure vertical magnetic material includes at least one of L10 structure FePt, L10 structure FePd, L10 structure CoPd, or L10 structure CoPt. The vertical magnetic structure includes magnetic layers and non-magnetic layers that are alternately and repeatedly stacked. For example, the vertical magnetic structure includes at least one of (Co/Pt) n, (CoFc/Pt) n, (CoFc/Pd) n, (Co/Pd) n, (Co/Ni) n, (CoNi/Pt) n, (CoCr/Pt) n, or (CoCr/Pd) n, where n is a number of stacks.

In the MRAM device 100 according to embodiments, the reliability of a device can be increased by forming the barrier layer 188 on a side surface of the second material layer 187b of the upper electrode 187 of the first information storage structure 180a disposed in the cell region CR, and forming only the barrier layer 188 instead of the second material layer 187b on an upper portion of the first material layer 187a of the upper electrode 187 of the second information storage structure 180b of a dummy cell adjacent to the core/peri region C/P R, thereby obtaining the MRAM device 100.

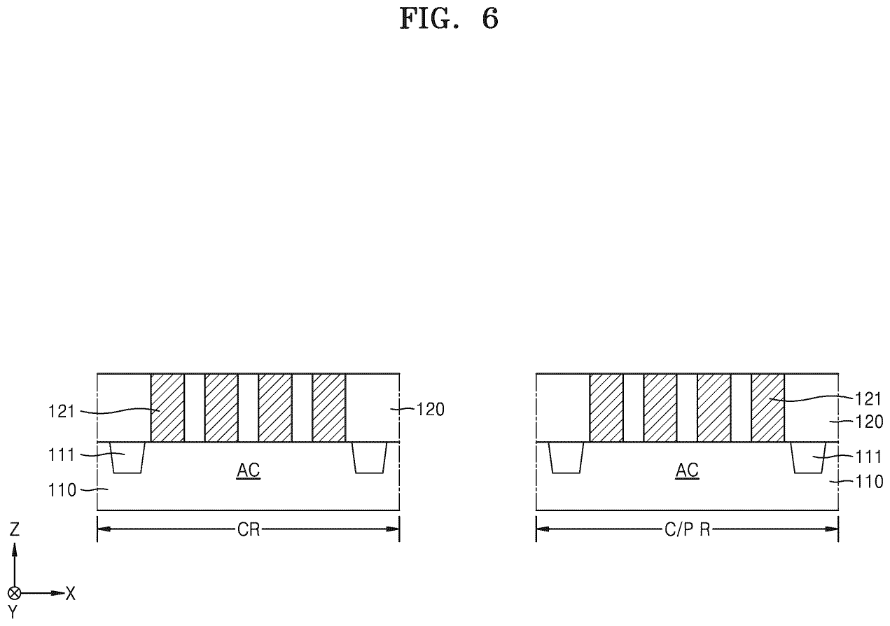

FIGS. 6 to 18 are cross-sectional views that illustrate a method of manufacturing an MRAM device 100, according to embodiments.

Referring to FIG. 6, in an embodiment, a substrate 110 that includes a cell region CR and a core/peri region C/P R is provided. A device isolation layer 111 is formed in the substrate 110. A lower interlayer insulation layer 120 and a lower conductive region 121 that passes through the lower interlayer insulation layer 120 are formed on the substrate 110. The lower interlayer insulation layer 120 and the lower conductive region 121 are formed be the same process in the cell region CR and the core/peri region C/P R of the substrate 110. The lower interlayer insulation layer 120 and the lower conductive region 121 are formed to the same vertical level in the cell region CR and the core/peri region C/P R of the substrate 110.

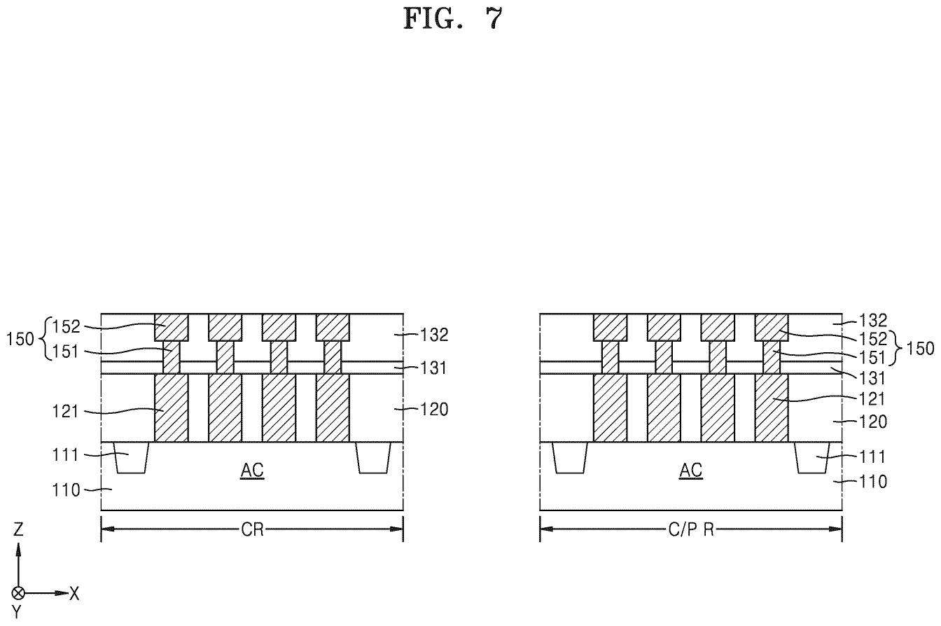

Referring to FIG. 7, in an embodiment, a first etch stop layer 131, a first interlayer insulation layer 132, and a first wiring structure 150 that passes through the first etch stop layer 131 and the first interlayer insulation layer 132 are formed on the lower interlayer insulation layer 120. For example, the first etch stop layer 131 and the first interlayer insulation layer 132 are formed, and a first wiring via 151 and a first wiring line 152 are sequentially formed.

The first etch stop layer 131, the first interlayer insulation layer 132, and the first wiring structure 150 that passes through the first etch stop layer 131 and the first interlayer insulation layer 132 are formed by the same process in the cell region CR and the core/peri region C/P R of the substrate 110. The first etch stop layer 131, the first interlayer insulation layer 132, and the first wiring structure 150 are formed to the same vertical level in the cell region CR and the core/peri region C/P R of the substrate 110.

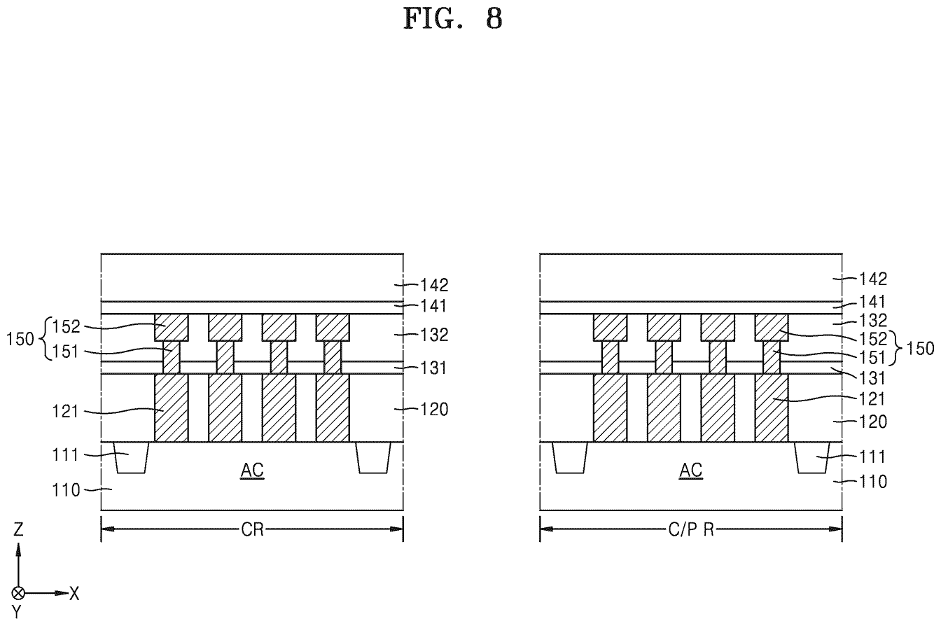

Referring to FIG. 8, in an embodiment, a second etch stop layer 141 and a second interlayer insulation layer 142 are formed on the first interlayer insulation layer 132. The second etch stop layer 141 and the second interlayer insulation layer 142 are formed by the same process in the cell region CR and the core/peri region C/P R of the substrate 110. The second etch stop layer 141 and the second interlayer insulation layer 142 are formed to the same vertical level in the cell region CR and the core/peri region C/P R of the substrate 110.

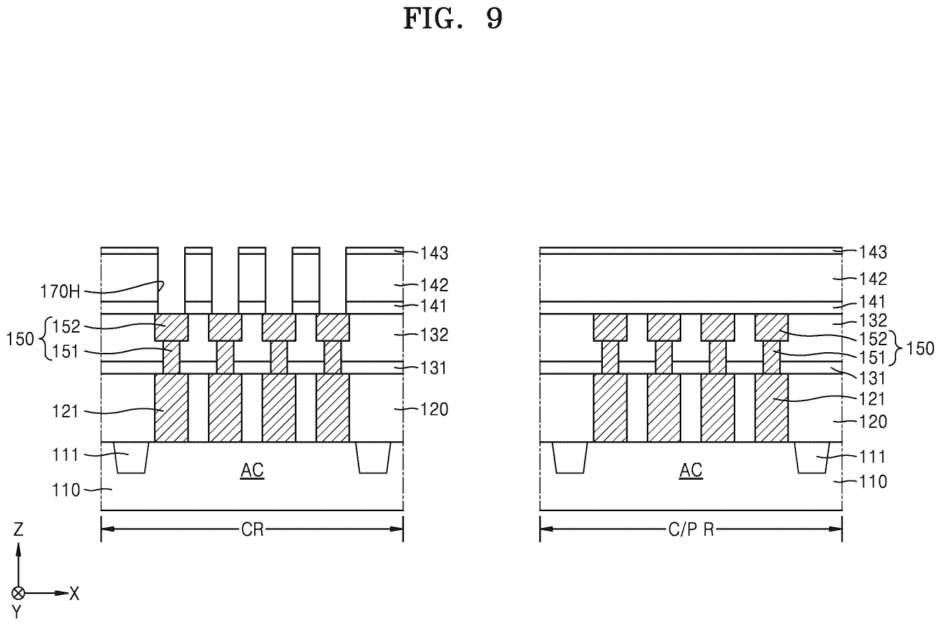

Referring to FIG. 9, in an embodiment, an upper etch stop layer 143 is formed on the second interlayer insulation layer 142 in the cell region CR and the core/peri region C/P R of the substrate 110. The upper etch stop layer 143 is formed at the same vertical level in the cell region CR and the core/peri region C/P R of the substrate 110.

A lower electrode contact hole 170H is formed that passes through the upper etch stop layer 143, the second interlayer insulation layer 142, and the second etch stop layer 141, in the cell region CR of the substrate 110. A first wiring line 152 of the first wiring structure 150 is exposed by the lower electrode contact hole 170H in the cell region CR.

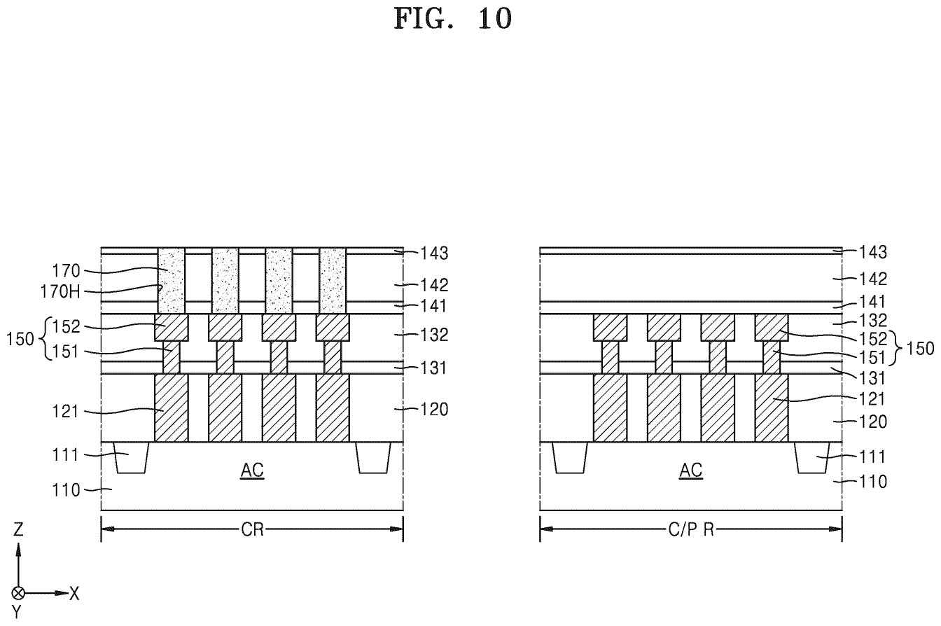

Referring to FIG. 10, in an embodiment, a lower electrode contact 170 that fills the lower electrode contact hole 170H is formed in the cell region CR of the substrate 110.

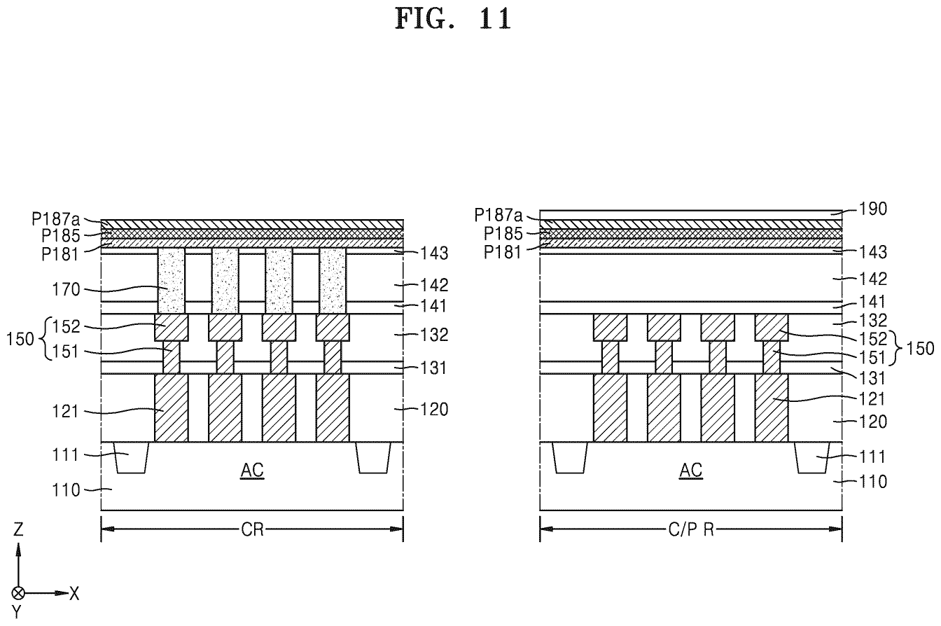

Referring to FIG. 11, in an embodiment, a preliminary lower electrode layer P181, a preliminary MTJ layer P185, and a preliminary first material layer P187a are sequentially formed on the lower electrode contact 170 in the cell region CR and the core/peri region C/P R of the substrate 110. A first etch stop layer 190 is additionally deposited on the preliminary first material layer P187a in the core/peri region C/P R. In an embodiment, the first etch stop layer 190 includes silicon nitride.

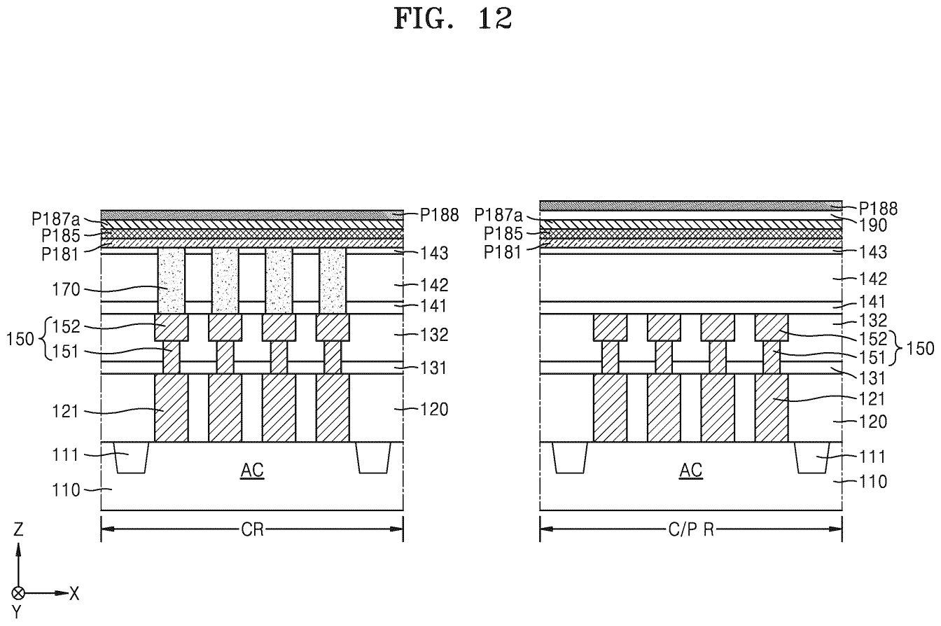

Referring to FIGS. 12, 13, and 14, in an embodiment, a preliminary barrier layer P188 is deposited on the preliminary first material layer P187a to have a predetermined thickness, and a portion of the preliminary barrier layer P188 of the cell region CR is etched. However, no etch pattern is formed at a portion where a dummy cell is to be formed.

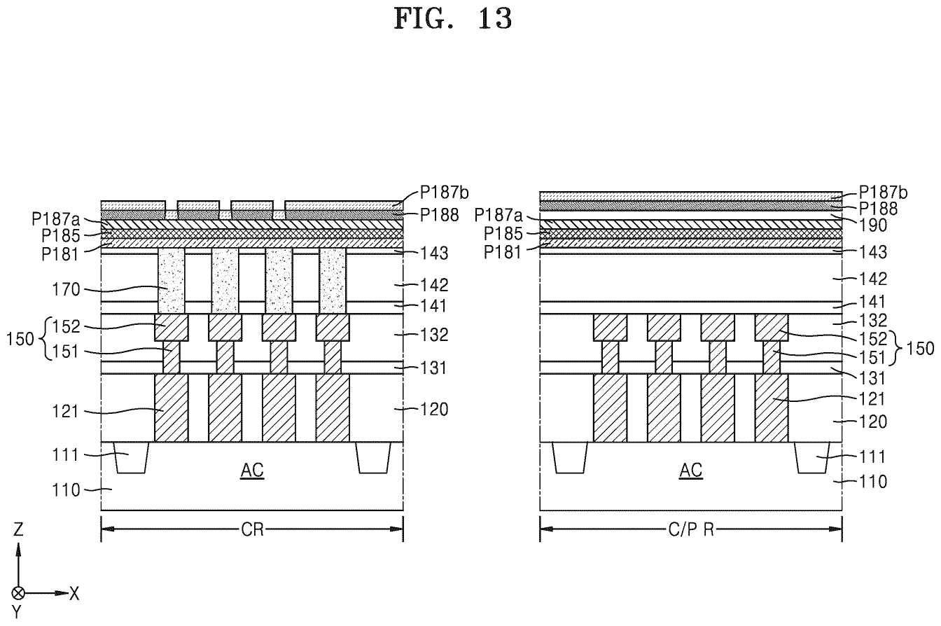

After the preliminary barrier layer P188 of the cell region CR is etched, a preliminary second material layer P187b is conformally formed in the cell region CR and the core/peri region C/P R (see FIG. 13). In an embodiment, the preliminary second material layer P187b is formed by an atomic layer deposition (ALD) process. The preliminary first material layer P187a and the preliminary second material layer P187b configure a preliminary upper electrode layer P187.

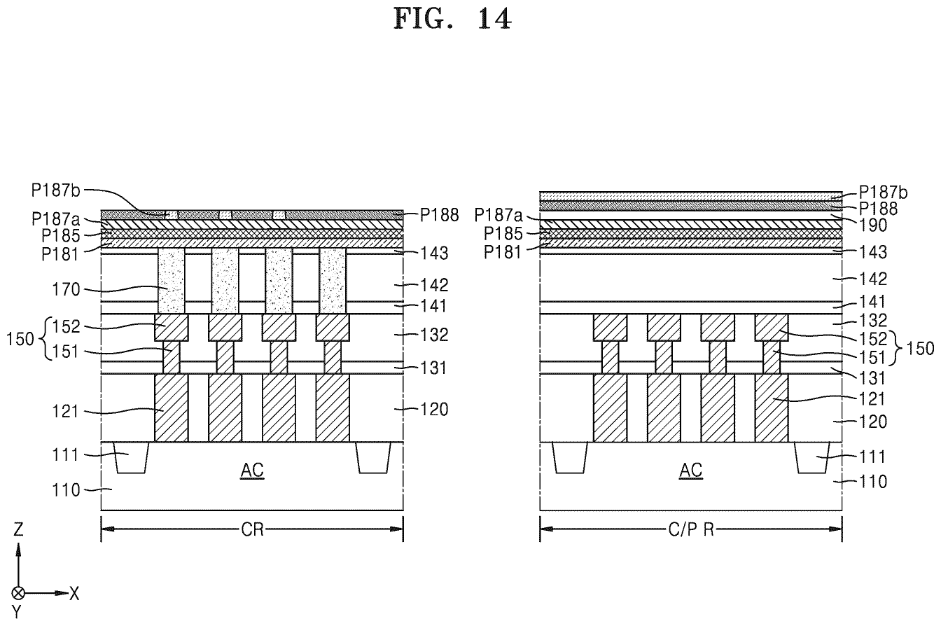

When a portion of an upper end of the preliminary second material layer P187b is etched by a chemical mechanical polishing (CMP) process and/or an etchback process, a result of FIG. 14 may be obtained.

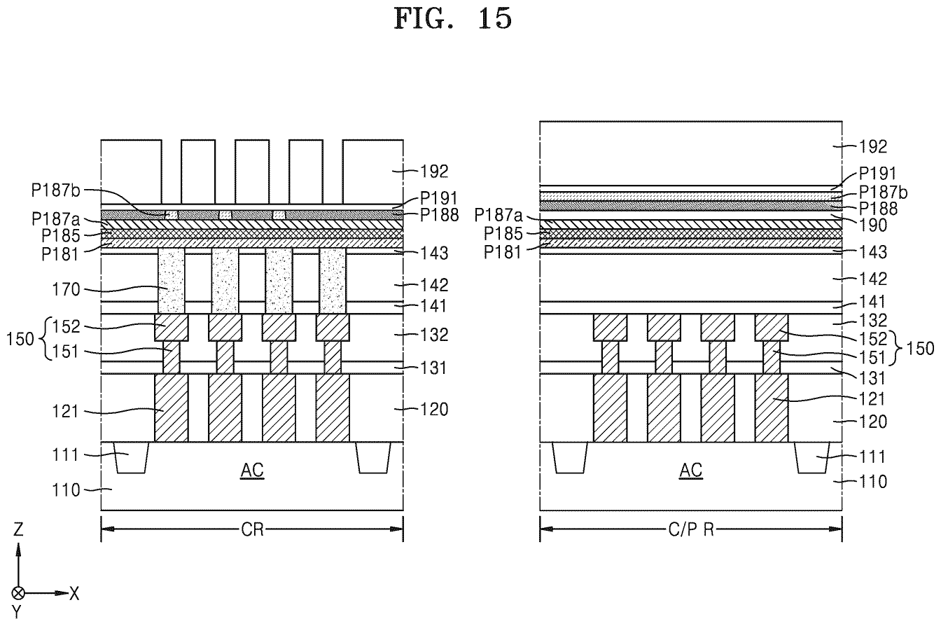

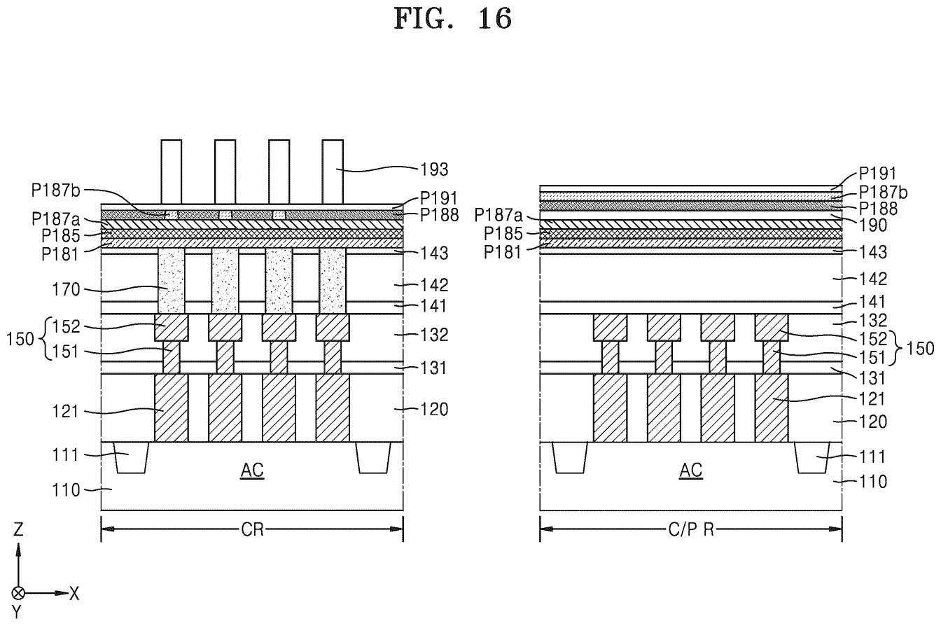

Referring to FIGS. 15 and 16, in an embodiment, a preliminary second etch stop layer P191 and a mold layer 192 are formed in the cell region CR and the core/peri region C/P R, and a recess portion is obtained by etching a portion of the mold layer 192 in the cell region CR through a photo process (see FIG. 15). In embodiments, the preliminary second etch stop layer P191 includes silicon nitride. An oxide layer 193 is formed in a recess portion formed between the mold layers 192 of FIG. 15, and a result of FIG. 16 is obtained by removing the mold layer 192 through an etchback process and an ashing process. The oxide layer 193 is disposed at a position that overlaps the preliminary second material layer P187b in a vertical direction (a Z direction). In addition, the oxide layer 193 is disposed on a portion where a dummy cell is to be formed.

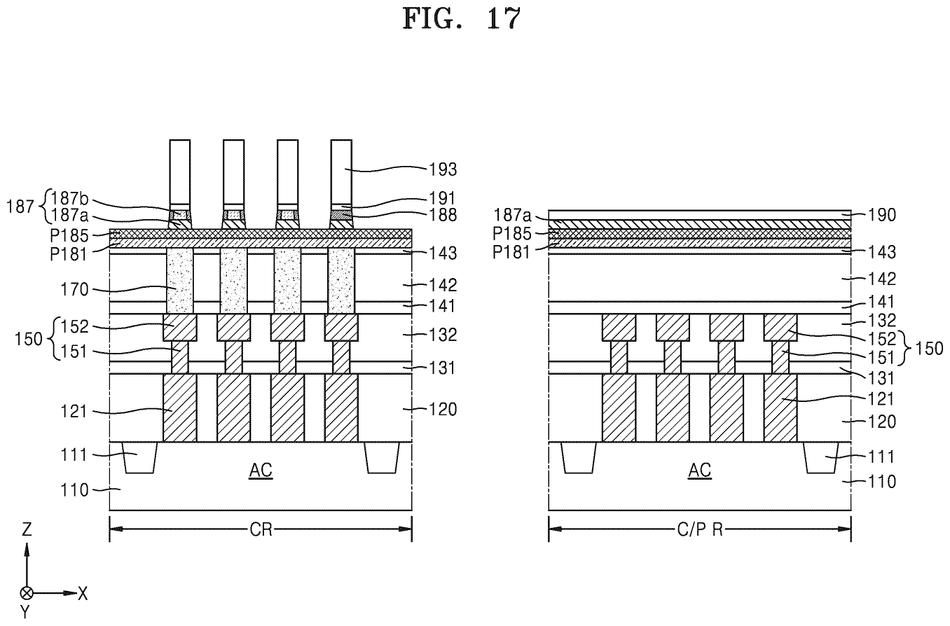

Referring to FIG. 17, an upper electrode 187 is formed by removing a portion of each of the preliminary first material layer P187a (see FIG. 16) and the preliminary second material layer P187b (see FIG. 16) from the cell region CR. A portion of the preliminary second etch stop layer P191 (see FIG. 16) is removed together in the process, and thus, a second etch stop layer 191 may remain on the upper electrode 187. In addition, in the core/peri region C/P R, the preliminary second etch stop layer P191 (see FIG. 16), the preliminary second material layer P187b (see FIG. 16), and the preliminary barrier layer P188 (see FIG. 16) are removed, and thus, the first etch stop layer 190 is exposed.

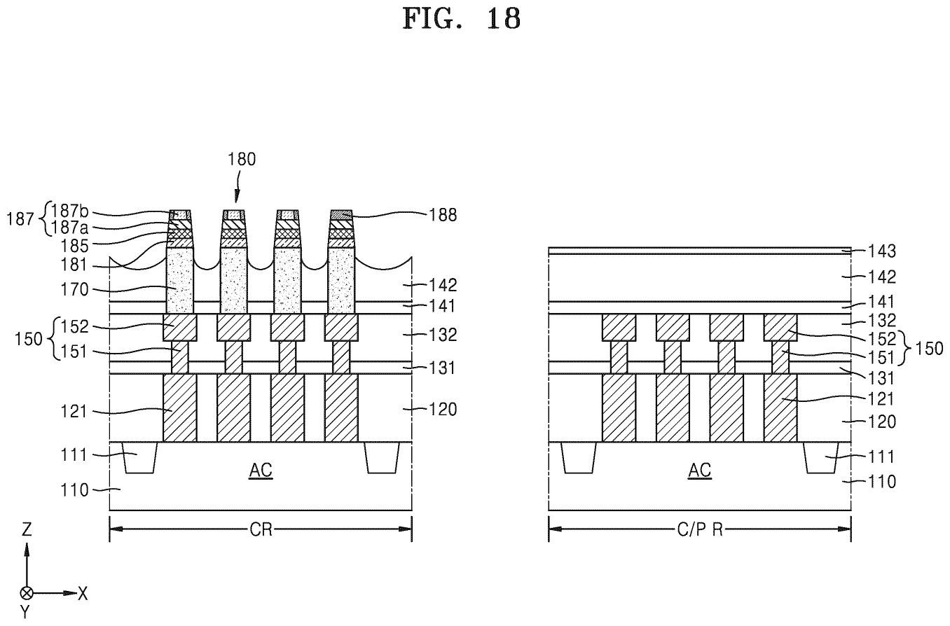

Referring to FIG. 18, a lower electrode 181 and an MTJ structure 185 are formed by etching a portion of each of the preliminary lower electrode layer P181 and the preliminary MTJ layer P185 in the cell region CR. A process of etching a portion of each of the preliminary lower electrode layer P181 and the preliminary MTJ layer P185 includes a process of using the upper electrode 187 as an etch mask.

In some embodiments, a process of removing a portion of each of the preliminary lower electrode layer P181 and the preliminary MTJ layer P185 to form the lower electrode 181 and the MTJ structure 185 uses an ion beam etching (IBE) process. A process that removes a portion of each of the preliminary lower electrode layer P181 and the preliminary MTJ layer P185 also removes a portion of each of the upper etch stop layer 143 and the second interlayer insulation layer 142 that surrounds a portion of the lower electrode contact 170.

A process that removes a portion of each of the preliminary lower electrode layer P181 and the preliminary MTJ layer P185 in the cell region CR of the substrate 110 also removes the preliminary MTJ layer P185 and the preliminary upper electrode layer P187 in the core/peri region C/P R, but does not remove the upper etch stop layer 143 and the second interlayer insulation layer 142 in the core/peri region C/P R. For example, a cover block is formed on the upper etch stop layer 143 in the middle of the etching process. The cover block is later removed.

Referring again to FIG. 2, in a result of FIG. 18, a silicon nitride layer 194 that has a predetermined thickness is formed in the cell region CR and the core/peri region C/P R. Therefore, the MRAM device 100 is formed.

In embodiments, the first information storage structure 180a disposed in the cell region CR includes the barrier layer 188 provided on a side surface of the second material layer 187b of the upper electrode 187, and the second information storage structure 180b includes only the barrier layer 188 disposed on the first material layer 187a of the upper electrode 187 in a dummy cell near the core/peri region C/P R.

Hereinabove, embodiments have been described in the specification with reference to the drawings. Therefore, it may be understood by those of ordinary skill in the art that various modifications and other equivalent embodiments may be implemented from the inventive concept. Accordingly, the spirit and scope of embodiments of the inventive concept may be defined based on the spirit and scope of the following claims.

While embodiments of the inventive concept have been particularly shown and described with reference to the drawings, it will be understood that various changes in form and details may be made therein without departing from the spirit and scope of the following claims.

What is claimed is:

1. A magnetoresistive random access memory device, comprising:
a cell region and a core peri region arranged in a first horizontal direction on a substrate;
a first interlayer insulation layer disposed on the substrate in the cell region and the core peri region;
a second interlayer insulation layer disposed on the first interlayer insulation layer;
a first wiring line disposed in the first interlayer insulation layer in the cell region and the core peri region;
a lower electrode contact disposed on the first wiring line in the cell region; and
first and second information storage structures disposed on the lower electrode contact in the cell region, wherein each of the first and second information storage structures includes a lower electrode and a magnetic tunnel junction (MTJ) structure disposed on the lower electrode,
wherein the first information storage structure further comprises an upper electrode disposed on the MTJ structure and a first barrier layer deposited on each sidewall of the upper electrode, and
the second information storage structure further comprises a second barrier layer disposed on the MTJ structure.

2. The magnetoresistive random access memory device of claim 1, wherein the first barrier layer is conformally formed along each sidewall of the upper electrode, and a first thickness and a second thickness of the barrier layer deposited on each sidewall of the upper electrode are equal to each other.

3. The magnetoresistive random access memory device of claim 1, wherein a thickness of the first barrier layer in the first horizontal direction does not exceed 3 nm.

4. The magnetoresistive random access memory device of claim 1, wherein the second information storage structure is disposed adjacent to the core peri region in the cell region.

5. The magnetoresistive random access memory device of claim 1, wherein a height of the first information storage structure in a vertical direction is greater than a height of the second information storage structure in a vertical direction.

6. The magnetoresistive random access memory device of claim 1, wherein the first barrier layer and the second barrier layer each comprise titanium oxide.

7. The magnetoresistive random access memory device of claim 1, wherein a height of the second barrier layer is not greater than a height of the upper electrode.

8. The magnetoresistive random access memory device of claim 1, wherein the barrier layer entirely covers an upper surface of the MTJ structure in the second information storage structure.

9. The magnetoresistive random access memory device of claim 1, wherein the first barrier layer and the second barrier layer comprise substantially a same material.

10. The magnetoresistive random access memory device of claim 1, wherein the lower electrode contact is in contact with the first wiring line.

11. The magnetoresistive random access memory device of claim 1, wherein the lower electrode contact passes through the second interlayer insulation layer.

12. A magnetoresistive random access memory device, comprising:
a cell region and a core peri region arranged in a first horizontal direction on a substrate;
a lower conductive region disposed in the cell region and the core peri region;
a first wiring structure that is connected to the lower conductive region in the cell region and the core peri region;
a lower electrode contact connected to the first wiring structure in the cell region; and
a first information storage structure disposed on the lower electrode contact, wherein the first information storage structure includes a lower electrode disposed on the lower electrode contact, a magnetic tunnel junction (MTJ) structure disposed on the lower electrode, and an upper electrode spaced apart from the lower electrode with the MTJ structure interposed therebetween,
wherein the first information storage structure further comprises a first barrier layer conformally disposed on both sidewalls of the upper electrode.

13. The magnetoresistive random access memory device of claim 12, further comprising at least one second information storage structure disposed in a region between the first information storage structure and a boundary portion between the cell region and the core peri region, in the cell region,
wherein the at least one second information storage structure comprises a lower electrode, an MTJ structure disposed on the lower electrode, and a second barrier layer disposed on the MTJ structure.

14. The magnetoresistive random access memory device of claim 13, wherein a height of the at least one second information storage structure is not greater than a height of the first information storage structure.

15. The magnetoresistive random access memory device of claim 12, wherein
the upper electrode comprises titanium nitride, and
the first barrier layer comprises titanium oxide and a thickness of the first barrier layer does not exceed 3 nm.

16. The magnetoresistive random access memory device of claim 12, wherein
the upper electrode has a trapezoid shape whose width in the first horizontal direction progressively increases toward the substrate, and
the first barrier layer has a profile inclined along a side surface of the upper electrode.

17. The magnetoresistive random access memory device of claim 13, wherein a height of the second barrier layer is not greater than a height of the upper electrode.

18. A magnetoresistive random access memory device comprising:
a cell region and a core peri region arranged in a first horizontal direction on a substrate;
lower conductive region disposed in the cell region and the core peri region;
first wiring structure that is connected to the lower conductive region in the cell region and the core peri region;
an interlayer insulation layer disposed on the substrate in the cell region and the core peri region;
wiring lines that pass through the interlayer insulation layer and are connected to the lower conductive region in the cell region and the core peri region;
a lower electrode contact disposed on the wiring lines;
a first information storage structure disposed on a first portion of the lower electrode contact, wherein the first information storage structure includes a lower electrode, a magnetic tunnel junction (MTJ) structure, and an upper electrode that are sequentially stacked;
a second information storage structure disposed on a second portion of the lower electrode contact, wherein the second information storage structure includes a lower electrode, an MTJ structure, and an upper barrier layer that are sequentially stacked; and
a barrier layer that includes titanium oxide and is conformally formed along each sidewall of the upper electrode of the first information storage structure,
wherein a vertical level of the wiring lines in the cell region and the core peri region is lower than or coplanar with a vertical level of a lower surface of the MTJ structure.

19. The magnetoresistive random access memory device of claim 18, wherein the second information storage structure is disposed in the cell region adjacent to the core peri region, and
a height of the second information storage structure is not greater than a height of the first information storage structure.

20. The magnetoresistive random access memory device of claim 18, wherein a conformal thickness of the barrier layer does not exceed 3 nm.
